(19) United States
(12) Patent Application Publication
(10) Pub. No.: US 2026/0253849 A1
(43) Pub. Date: Aug. 27, 2026

(54) SUBSTRATE SUPPORT AND PLASMA PROCESSING APPARATUS

(71) Applicant: Tokyo Electron Limited, Tokyo (JP)

(72) Inventors: Naoki IMOTO, Miyagi (JP); Kazuki OSHIMA, Miyagi (JP); Shuhei YAMABE, Miyagi (JP); Hajime TAMURA, Miyagi (JP); Ryo CHIBA, Miyagi (JP)

(73) Assignee: Tokyo Electron Limited, Tokyo (JP)

(21) Appl. No.: 19/649,927

(22) Filed: Apr. 16, 2026

Related U.S. Application Data
(63) Continuation of application No. PCT/JP2024/037586, filed on Oct. 22, 2024.

(30) Foreign Application Priority Data
Oct. 26, 2023 (JP) 2023-183943

(51) Int. Cl. H01J 37/32

(52) U.S. Cl. CPC H01J 37/32715; H01J 2237/2007

(57) ABSTRACT

A disclosed substrate support includes a base, an electrostatic chuck, a sleeve, a first member, and a second member. The electrostatic chuck has a first surface including a substrate supporting surface and a second surface, and provides a first through hole penetrating from the first surface to the second surface. The sleeve is fixed within the base and defines a second through hole that is aligned with and communicates with the first through hole. The sleeve includes a fixing portion that partially defines the inner surface of the sleeve. The first member is within the first through hole. The second member is at least within the second through hole, and supports the first member. The second member includes a fixed portion that is fixed by the fixing portion. In a lateral direction, a width of the fixing portion is smaller than a width of the fixed portion.

### CROSS-REFERENCE TO RELATED APPLICATIONS

This application is a continuation application of PCT Application No. PCT/JP2024/037586, filed on Oct. 22, 2024, which claims the benefit of priority from Japanese Patent Application No. 2023-183943, filed on Oct. 26, 2023. The entire contents of the above listed PCT and priority applications are incorporated herein by reference.

### BACKGROUND

### Field

Example embodiments of the present disclosure relate to a substrate support and a plasma processing apparatus.

### Description of the Related Art

A plasma processing apparatus is used in plasma processing of a substrate. The plasma processing apparatus described in Japanese Unexamined Patent Publication No. 2019-149422 below includes a plasma processing chamber and a substrate support. The substrate support is disposed in the plasma processing chamber. The substrate support includes an electrostatic chuck including a first through hole formed therein, a base including a second through hole formed therein and communicating with the first through hole, and an embedded member disposed within the first through hole and the second through hole.

### SUMMARY

In one example embodiment, a substrate support is provided. The substrate support includes a base, an electrostatic chuck, a sleeve, a first member, and a second member. The electrostatic chuck is on the base. The electrostatic chuck has a first surface including a substrate supporting surface and a second surface on the opposite side from the first surface, and defines a first through hole penetrating from the first surface to the second surface. The sleeve has a tubular shape and is fixed within the base. The sleeve defines, as an inner hole thereof, a second through hole that is aligned with the first through hole and communicates with the first through hole. The first member is within the first through hole. The second member has a columnar shape, is at least within the second through hole, and supports the first member. The first member and the second member define a gas flow path within the first through hole and within the second through hole. The sleeve includes a fixing portion that partially defines the inner surface of the sleeve. The second member includes a fixed portion that is fixed by the fixing portion. A width of the fixing portion in a lateral direction orthogonal to the central axes of both the sleeve and the second member is smaller than a width of the fixed portion in the lateral direction.

### BRIEF DESCRIPTION OF THE DRAWINGS

FIG. 1 is a diagram schematically illustrating a plasma processing system according to one example embodiment.

FIG. 2 is a diagram schematically illustrating a plasma processing apparatus according to one example embodiment.

FIG. 3 is a partially enlarged cross-sectional view illustrating a substrate support according to one example embodiment.

FIG. 4 is a partially enlarged cross-sectional view illustrating a configuration of a first member and an electrostatic chuck according to one example embodiment.

FIG. 5 is a perspective view illustrating a part of a second member according to one example embodiment.

FIG. 6 is a partially enlarged cross-sectional view illustrating a substrate support according to another example embodiment.

FIG. 7 is a partially enlarged cross-sectional view illustrating a substrate support according to yet another example embodiment.

FIG. 8 is a cross-sectional view illustrating a configuration of a second member and a sleeve according to yet another example embodiment.

FIG. 9 is a partially enlarged cross-sectional view illustrating a substrate support according to yet another example embodiment.

FIG. 10 is a partially enlarged cross-sectional view illustrating a substrate support according to yet another example embodiment.

FIG. 11 is a partially enlarged cross-sectional view illustrating a substrate support according to yet another example embodiment.

FIG. 12 is a partially enlarged cross-sectional view illustrating a substrate support according to yet another example embodiment.

FIG. 13 is a partially enlarged cross-sectional view illustrating a substrate support according to yet another example embodiment.

FIG. 14 is a partially enlarged cross-sectional view illustrating a substrate support according to yet another example embodiment.

### DETAILED DESCRIPTION

Hereinafter, various example embodiments will be described in detail with reference to the drawings. In the drawings, the same or equivalent portions are denoted by the same reference signs.

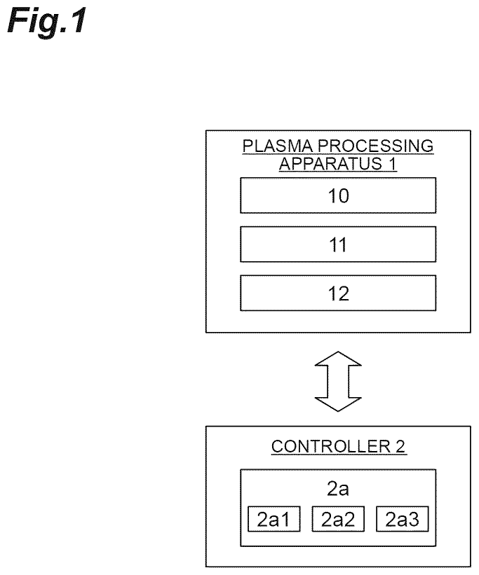

FIG. 1 illustrates an example configuration of a plasma processing system. In an embodiment, the plasma processing system includes a plasma processing apparatus 1 and a controller 2. The plasma processing system is an example substrate processing system, and the plasma processing apparatus 1 is an example substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2a1, a storage 2a2, and a communication interface 2a3. The controller 2 is implemented in, for example, a computer 2a. The processor 2al may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2al reads to execute the program from the storage 2a2. The medium may be of any type which can be accessed by the computer 2a or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

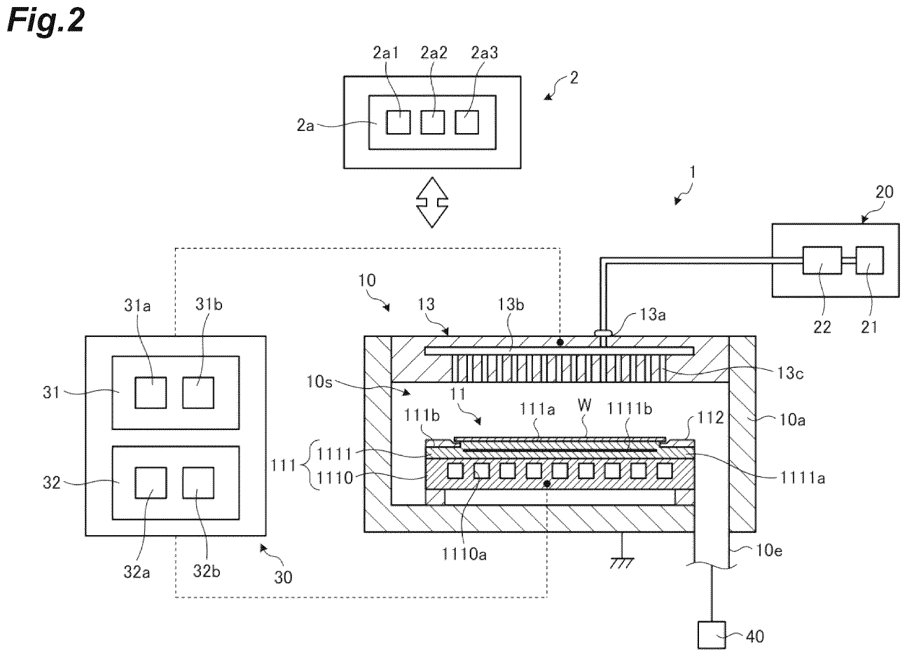

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, an electric power source 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in the plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 has a central region 111a for supporting a substrate W and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the ring assembly 112.

In an embodiment, the body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In an embodiment, the ceramic member 1111a also has the annular region 111b. Any other member, such as an annular electrostatic chuck or an annular insulating member, surrounding the electrostatic chuck 1111 may have the annular region 111b. In this case, the ring assembly 112 may be disposed on either the annular electrostatic chuck or the annular insulating member, or both the electrostatic chuck 1111 and the annular insulating member. At least one RF/DC electrode coupled to an RF source 31 and/or a DC source 32 described below may be disposed in the ceramic member 1111a. In this case, the at least one RF/DC electrode functions as the lower electrode. If a bias RF signal and/or DC signal described below are supplied to the at least one RF/DC electrode, the RF/DC electrode is also called a bias electrode. It is noted that the conductive member of the base 1110 and the at least one RF/DC electrode may each function as a lower electrode. The electrostatic electrode 1111b may also function as a lower electrode. The substrate support 11 accordingly includes at least one lower electrode.

The ring assembly 112 includes one or more annular members. In an embodiment, the annular members include one or more edge rings and at least one cover ring. The edge ring is composed of a conductive or insulating material, whereas the cover ring is composed of an insulating material.

The substrate support 11 may also include a temperature adjusting module that is configured to adjust at least one of the electrostatic chuck 1111, the ring assembly 112, and the substrate to a target temperature. The temperature adjusting module may be a heater, a heat transfer medium, a flow passage 1110a, or any combination thereof. A heat transfer fluid, such as brine or gas, flows into the flow passage 1110a. In an embodiment, the flow passage 1110a is formed in the base 1110, and one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include at least one flow modulation device that can modulate or pulse the flow of the at least one process gas.

The electric power source 30 includes an RF source 31 coupled to the plasma processing chamber 10 through at least one impedance matching circuit. The RF source 31 is configured to supply at least one RF signal (RF power) to at least one lower electrode and/or at least one upper electrode. A plasma is thereby formed from at least one process gas supplied into the plasma processing space 10s. Thus, the RF source 31 can function as at least part of the plasma generator 12. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the at least one lower electrode and/or the at least one upper electrode through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the at least one lower electrode and/or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the plasma processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses may have a rectangular, trapezoidal, or triangular waveform, or a combined waveform thereof. In an embodiment, a waveform generator for generating a sequence of voltage pulses from the DC signal is disposed between the first DC generator 32a and the at least one lower electrode. The first DC generator 32a and the waveform generator thereby function as a voltage pulse generator. In the case that the second DC generator 32b and the waveform generator function as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

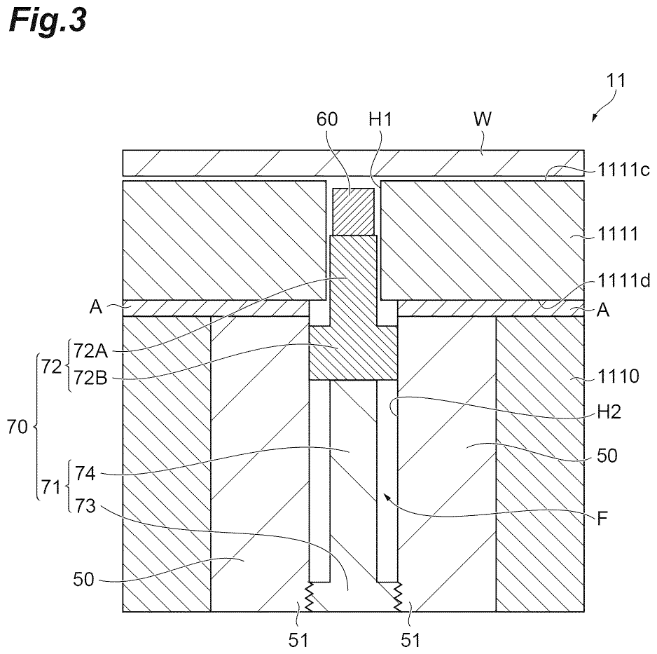

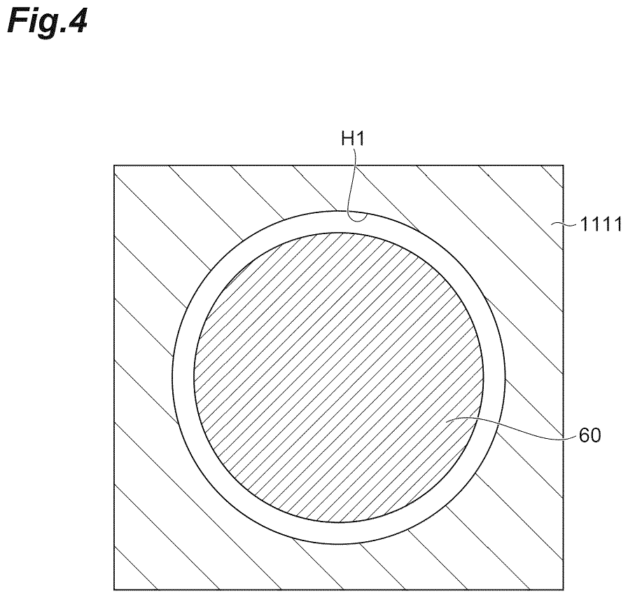

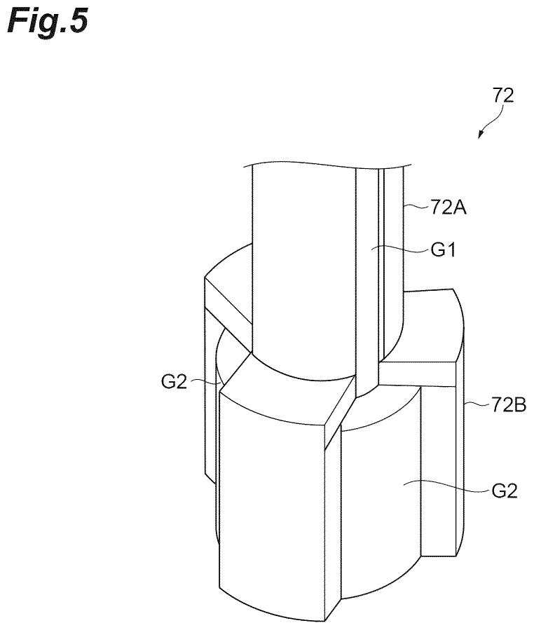

Hereinafter, a substrate support according to one example embodiment will be described with reference to FIGS. 3 to 5. FIG. 3 is a partially enlarged cross-sectional view illustrating the substrate support according to one example embodiment. FIG. 4 is a partially enlarged cross-sectional view illustrating a configuration of a first member and an electrostatic chuck according to one example embodiment. FIG. 5 is a perspective view illustrating a part of a second member according to one example embodiment.

The substrate support 11 illustrated in FIG. 3 can be used as the substrate support 11 of the plasma processing apparatus 1. As illustrated in FIG. 3, the substrate support 11 includes a base 1110, an electrostatic chuck 1111, a sleeve 50, a first member 60, and a second member 70.

The base 1110 may include a metal such as aluminum. Alternatively, the base 1110 may include a brittle material such as ceramic. The base 1110 may include a conductive ceramic. Examples of the conductive ceramic include a material in which conductive particles such as metal are dispersed in a ceramic matrix, or a metal matrix composite (MMC: Metal Matrix Composites) in which ceramic is dispersed in a metal matrix. The metal constituting the base 1110 may include at least one selected from the group consisting of silicon, aluminum, titanium, tungsten, and molybdenum. The ceramic constituting the base 1110 may include at least one selected from the group consisting of aluminum oxide, aluminum nitride, and silicon carbide.

The electrostatic chuck 1111 is on the base 1110. The electrostatic chuck 1111 is bonded to the upper surface of the base 1110. In the present embodiment, the electrostatic chuck 1111 is bonded to the base 1110 by a bonding material A. The bonding material A may include, for example, an organic adhesive. The electrostatic chuck 1111 may be bonded to the base 1110 by metal bonding using a metal such as a brazing material.

As illustrated in FIG. 3, the electrostatic chuck 1111 has a first surface 1111c and a second surface 1111d. The first surface 1111c includes the substrate supporting surface (or the central region 111a), i.e., the surface that supports the substrate W placed thereon. The second surface 1111d is a surface on the opposite side from the first surface 1111c. The second surface 1111d is located between the first surface 1111c and the base 1110. The second surface 1111d is bonded to the upper surface of the base 1110 by the bonding material A.

The electrostatic chuck 1111 provides a first through hole H1. The first through hole H1 penetrates the electrostatic chuck 1111 from the first surface 1111c to the second surface 1111d. The first through hole H1 may penetrate the electrostatic chuck 1111 in the vertical direction. The first through hole H1 may have, for example, a circular cross-sectional shape. The substrate support 11 may provide a plurality of first through holes H1.

The sleeve 50 is fixed to the base 1110. The sleeve 50 is formed of an insulating material and has a tubular shape. In the example illustrated in FIG. 3, the sleeve 50 is a single member having a tubular shape. The sleeve 50 defines a second through hole H2 as an inner hole thereof. That is, the inner surface of the sleeve 50 defines the second through hole H2 as the inner hole of the sleeve 50. The second through hole H2 is aligned with the first through hole H1 and communicates with the first through hole H1. The sleeve 50 may be fixed to the base 1110 by a bonding layer. The sleeve 50 may also be detachably attached to the base 1110 without a bonding layer.

As illustrated in FIG. 3, the width of the second through hole H2 may be larger than the width of the first through hole H1. The width of the second through hole H2 is defined by the length of the second through hole H2 in the lateral direction orthogonal to the central axis of the second through hole H2, and the width of the first through hole H1 is defined by the length of the first through hole H1 in the lateral direction orthogonal to the central axis of the first through hole H1. The width of the second through hole H2 may be smaller than the width of the first through hole H1, or may be equal to the width of the first through hole H1.

The first member 60 is within the first through hole H1. The first member 60 has a columnar shape. The first member 60 may have a cylindrical shape. The length of the first member 60 in the vertical direction is shorter than the length of the electrostatic chuck 1111 in the vertical direction. The width of the first member 60 in the lateral direction is smaller than the width of the first through hole H1 in the lateral direction. The first member 60 includes silicon carbide or ceramic. The length of the first member 60 in the vertical direction and the length of the electrostatic chuck 1111 in the vertical direction are defined by their respective lengths in the direction along the central axis of the first member 60. Furthermore, the width of the first member 60 in the lateral direction and the width of the first through hole H1 in the lateral direction are defined by their respective lengths in the direction orthogonal to the central axis of the first member 60.

As described above, the width of the first member 60 in the lateral direction is smaller than the width of the first through hole H1 in the lateral direction. Therefore, as illustrated in FIG. 4, a first gap is formed between the first member 60 and the inner surface of the electrostatic chuck 1111 that provides the first through hole H1. That is, the first member 60 forms a first gap between the inner surface of the electrostatic chuck 1111 defining the first through hole H1 and the first member 60. The first member 60 forms the first gap between the inner surface of the electrostatic chuck 1111 and the first member 60 over the entire circumference thereof. The first gap extends from the upper end to the lower end of the side surface of the first member 60.

The second member 70 is disposed below the first member 60 and supports the first member 60. The second member 70 has a columnar shape and is at least within the second through hole H2. In the example illustrated in FIG. 3, the second member 70 is within the first through hole H1 and within the second through hole H2. The second member 70 may include a first rod 71 and a second rod 72.

The first rod 71 supports the second rod 72 within the second through hole H2. The first rod 71 has a columnar shape and is within the second through hole H2. The first rod 71 is fixed to the sleeve 50. This fixes the position of the first rod 71 within the second through hole H2. Details of the fixing of the first rod 71 will be described later. The first rod 71 forms a second gap between the inner surface of the sleeve 50 defining the second through hole H2 and the first rod 71. The first rod 71 may include ceramic.

The second rod 72 has a columnar shape and extends between the first rod 71 and the first member 60. The second rod 72 extends from the first through hole H1 to the second through hole H2. The second rod 72 may include polytetrafluoroethylene. The second rod 72 supports the first member 60 within the first through hole H1.

The second rod 72 may include a first portion 72A and a second portion 72B. The first portion 72A extends from within the first through hole H1 to within the second through hole H2. The first portion 72A is in contact with the lower end of the first member 60 within the first through hole H1 and supports the first member 60.

As illustrated in FIG. 5, the side surface of the first portion 72A defines one or more grooves G1. The one or more grooves G1 extend along the side surface of the first portion 72A from the upper end to the lower end of the side surface of the first portion 72A. As illustrated in FIG. 5, a plurality of grooves G1 may extend along the side surface of the first portion 72A and may be arranged along the circumferential direction. The number of the plurality of grooves G1 is, for example, “3”.

The one or more grooves G1 provide one or more third gaps between the side surface of the first portion 72A and the inner surface of the electrostatic chuck 1111 defining the first through hole H1. The one or more third gaps extend from the upper end to the lower end of the side surface of the first portion 72A.

The second portion 72B supports the first portion 72A within the second through hole H2. The second portion 72B is disposed only within the second through hole H2 and is continuous with the first portion 72A. Similarly to the first portion 72A, the side surface of the second portion 72B also defines one or more grooves G2 extending from the upper end to the lower end thereof. The one or more grooves G2 provide one or more fourth gaps between the second portion 72B and the inner surface of the sleeve 50 defining the second through hole H2. The one or more fourth gaps extend from the upper end to the lower end of the side surface of the second portion 72B.

The one or more first gaps, the second gap, the one or more third gaps, and the one or more fourth gaps described above define a gas flow path F. That is, the gas flow path F extends through the first through hole H1 and the second through hole H2.

The gas flow path F is provided to supply a heat transfer gas from a heat transfer gas supply (not illustrated) to a space between the first surface 1111c of the electrostatic chuck 1111 and the substrate W. The heat transfer gas includes, for example, helium gas.

Hereinafter, the fixing of the first rod 71 to the sleeve 50 will be described in further detail. As illustrated in FIG. 3, the sleeve 50 includes a fixing portion 51. The fixing portion 51 is a portion for fixing the first rod 71 to the sleeve 50. The fixing portion 51 partially defines the inner surface of the sleeve 50. The fixing portion 51 may define the inner surface of a part of the sleeve 50 including the lower end of the sleeve 50. The fixing portion 51 includes an internal thread. More specifically, the inner surface of the sleeve 50 defined by the fixing portion 51 includes an internal thread.

The second member 70 includes a fixed portion 73. The fixed portion 73 is a portion that is fixed to the sleeve 50 by the fixing portion 51. The width of the fixing portion 51 in the lateral direction is smaller than the width of the fixed portion 73 in the lateral direction. Here, the width of the fixing portion 51 and the width of the fixed portion 73 in the lateral direction are defined by the length in the direction orthogonal to the central axes of both the sleeve 50 and the second member 70.

In the example illustrated in FIG. 3, the first rod 71 of the second member 70 includes the fixed portion 73. More specifically, the first rod 71 includes the fixed portion 73 and a body 74. The body 74 supports the second rod 72 disposed thereon within the second through hole H2. The fixed portion 73 and the body 74 are continuous with each other. The width of the body 74 in the lateral direction is smaller than the width of the fixed portion 73 in the lateral direction. The width of the body 74 in the lateral direction may be larger than the width of the fixed portion 73 in the lateral direction, or may be equal to that width.

The outer surface of the fixed portion 73 includes an external thread. The external thread of the fixed portion 73 is threadedly engaged with the internal thread of the fixing portion 51. Therefore, the width of the fixing portion 51 in the lateral direction is partially smaller than the width of the fixed portion 73 in the lateral direction.

When the fixing portion 51 includes an internal thread, the width of the fixing portion 51 in the lateral direction is defined by the minimum distance between the inner surfaces of the sleeve 50 defined by the fixing portion 51 in the direction orthogonal to the central axes of both the sleeve 50 and the second member 70. This minimum distance between the inner surfaces of the sleeve 50 defined by the fixing portion 51 is also called the minor diameter of the internal thread included in the fixing portion 51. Therefore, when the fixing portion 51 includes an internal thread, the width of the fixing portion 51 in the lateral direction is defined by the minor diameter of the internal thread (the minimum diameter of the internal thread).

When the fixed portion 73 includes an external thread, the width of the fixed portion 73 in the lateral direction is defined by the maximum diameter of the external thread. Such a maximum diameter of the external thread is also called the nominal diameter. Therefore, when the fixed portion 73 includes an external thread, the width of the fixed portion 73 in the lateral direction is defined by the nominal diameter of the external thread.

In the substrate support 11, the first member 60 and the second member 70 are within the first through hole H1 and within the second through hole H2. The first member 60 and the second member 70 suppress electrical discharge within the first through hole H1 and within the second through hole H2 while providing the gas flow path F for the heat transfer gas within the first through hole H1 and within the second through hole H2.

Further, in the substrate support 11, since the fixed portion 73 is fixed by the fixing portion 51, even if thermal contraction of the second member 70 occurs, an increase in the distance between the first member 60 and the rear surface of the substrate W is suppressed. Therefore, with the substrate support 11, electrical discharge between the substrate W and the electrostatic chuck 1111 is suppressed.

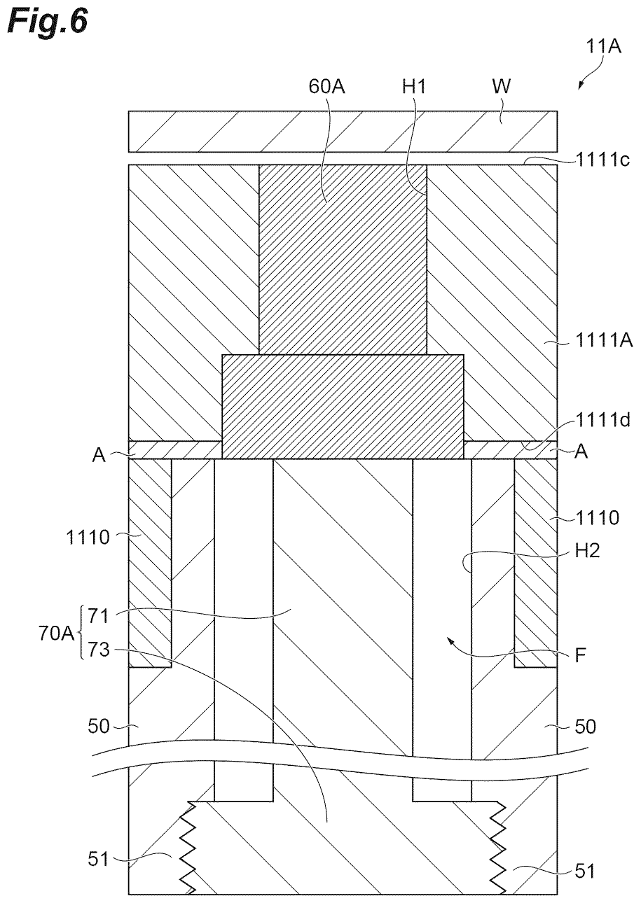

Next, a substrate support 11A according to another example embodiment will be described with reference to FIG. 6. FIG. 6 is a partially enlarged cross-sectional view illustrating the substrate support according to another example embodiment. In the following, the differences between the substrate support 11A illustrated in FIG. 6 and the substrate support 11 according to the embodiment described above will be mainly described.

The substrate support 11A includes an electrostatic chuck 1111A, a first member 60A, and a second member 70A in place of the electrostatic chuck 1111, the first member 60, and the second member 70.

The electrostatic chuck 1111A includes a counterbore defining the first through hole H1. The first member 60A may include, for example, a small-diameter portion and a large-diameter portion continuous with the small-diameter portion. As illustrated in FIG. 6, the first member 60A abuts against the surface defining the counterbore. Thus, the position of the first member 60A within the first through hole H1 is determined.

The length of the first member 60A may be equal to the length of the electrostatic chuck 1111A. Therefore, in the substrate support 11A, only the first member 60A may be disposed within the first through hole H1.

The second member 70A may be a single member. The second member 70A may include only the first rod 71. In the substrate support 11A, the first rod 71 supports the first member 60. Further, in the substrate support 11A, the second member 70A, i.e., the first rod 71, includes ceramic.

The first member 60A provides a flow passage extending helically. This flow passage communicates with the gap between the first rod 71 and the inner surface of the sleeve 50 providing the second through hole H2 through the side surface and interior of the first member 60A, thereby defining the gas flow path F. The manner in which the fixed portion 73 is fixed to the fixing portion 51 in the substrate support 11A is the same as that in the substrate support 11, and therefore the description thereof is omitted.

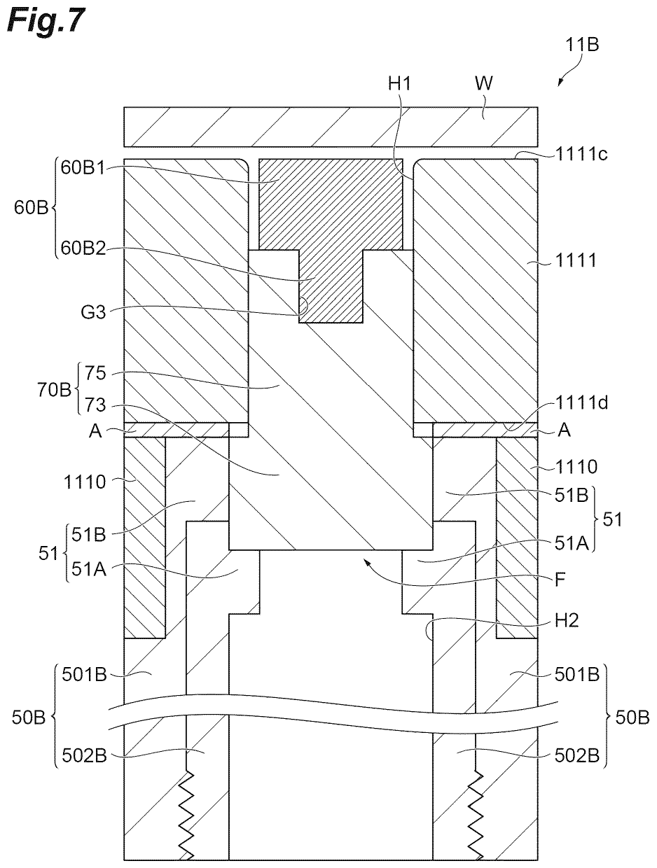

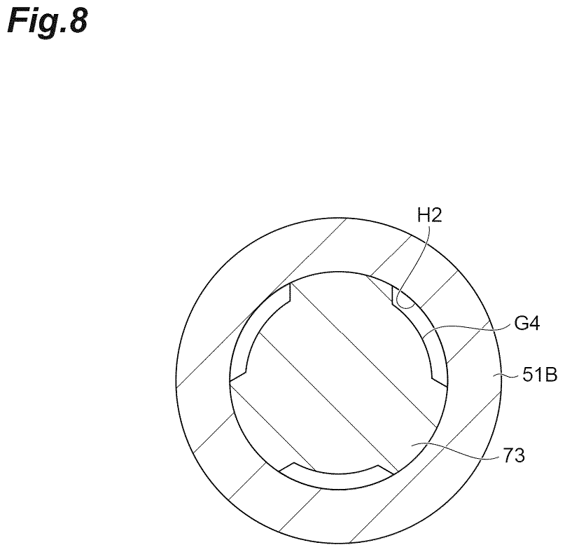

Next, a substrate support 11B according to yet another example embodiment will be described with reference to FIGS. 7 and 8. FIG. 7 is a partially enlarged cross-sectional view illustrating the substrate support according to yet another example embodiment. FIG. 8 is a cross-sectional view illustrating a configuration of a second member and an electrostatic chuck according to yet another example embodiment. In the following, the differences between the substrate support 11B illustrated in FIG. 7 and the substrate support 11 according to the embodiment described above will be mainly described.

The substrate support 11B includes a sleeve 50B, a first member 60B, and a second member 70B in place of the sleeve 50, the first member 60, and the second member 70.

The sleeve 50B includes a first sleeve 501B and a second sleeve 502B. The first sleeve 501B is fixed to the base 1110. The first sleeve 501B may be fixed to the base 1110 by a bonding layer. The first sleeve 501B may also be detachably attached to the base 1110 without a bonding layer. The first sleeve 501B has a tubular shape. The second sleeve 502B is disposed within the inner hole of the first sleeve 501B and is fixed to the first sleeve 501B. That is, the sleeve 50B has a two-layer structure formed of two tubular layers. The first sleeve 501B and the second sleeve 502B may be threadedly engaged with each other at their lower end portions. The first sleeve 501B and the second sleeve 502B may be bonded to each other at their lower end portions by, for example, an adhesive.

The sleeve 50B also provides the second through hole H2 as an inner hole thereof, similarly to the sleeve 50. More specifically, in the sleeve 50B, a part of the inner surface of the first sleeve 501B and the entire inner surface of the second sleeve 502B define the second through hole H2.

The first member 60B includes a first portion 60B1 and a second portion 60B2. The first portion 60B1 has a columnar shape. The width of the first portion 60B1 in the lateral direction is smaller than the width of the first through hole H1 in the lateral direction. Therefore, a gap is formed between the first portion 60B1 and the inner surface of the electrostatic chuck 1111 providing the first through hole H1.

The second portion 60B2 is a portion extending downward from the first portion 60B1. The second portion 60B2 has a columnar shape, and width thereof in the lateral direction is smaller than the width of the first portion 60B1.

The second member 70B is a single member and includes a fixed portion 73 and a support portion 75. The second member 70B may include polytetrafluoroethylene.

The support portion 75 has a columnar shape and extends upward from the fixed portion 73. The support portion 75 is within the first through hole H1. The support portion 75 provides a groove G3 at upper end portion thereof. The second portion 60B2 of the first member 60B is fitted into the groove G3. Thus, the first member 60B is supported by the support portion 75 within the first through hole H1.

In the substrate support 11B, the fixing portion 51 includes a small-diameter portion 51A and a large-diameter portion 51B. The second sleeve 502B configures the small-diameter portion 51A and the first sleeve 501B configures the large-diameter portion 51B. The small-diameter portion 51A has a diameter smaller than the width of the fixed portion 73 in the lateral direction. The large-diameter portion 51B has a diameter larger than the width of the fixed portion 73 in the lateral direction and is above the small-diameter portion 51A. The respective inner surfaces of the small-diameter portion 51A and the large-diameter portion 51B define a part of the second through hole H2.

In the substrate support 11B, the fixed portion 73 is above the small-diameter portion 51A and inside the large-diameter portion 51B. Furthermore, in the substrate support 11B, the fixed portion 73 is held between the small-diameter portion 51A and the electrostatic chuck 1111. As illustrated in FIG. 7, the bonding material A need not be disposed between the fixed portion 73 and the electrostatic chuck 1111. Furthermore, in the substrate support 11B, the side surface of the support portion 75 defines one or more grooves (not illustrated). The one or more grooves extend from the upper end to the lower end of the side surface of the support portion 75. For example, the side surface of the support portion 75 may define a plurality of grooves as the one or more grooves. The plurality of grooves may be arranged along the circumferential direction. The number of the plurality of grooves is, for example, “3”.

The one or more grooves defined by the support portion 75 form a gap between the side surface of the support portion 75 and the inner surface of the electrostatic chuck 1111 defining the first through hole H1. This gap extends from the upper end to the lower end of the support portion 75.

The fixed portion 73 is continuous with the support portion 75 and extends downward from the support portion 75. The side surface of the fixed portion 73 defines one or more grooves G4. The one or more grooves G4 extend from the upper end to the lower end of the side surface of the fixed portion 73. The side surface of the fixed portion 73 may define a plurality of grooves G4. The plurality of grooves G4 may be arranged along the circumferential direction. The number of the plurality of grooves G4 is, for example, “3”.

The one or more grooves G4 defined by the fixed portion 73 form, as illustrated in FIG. 8, a gap between the side surface of the fixed portion 73 and the inner surface of the large-diameter portion 51B defining the second through hole H2. This gap extends from the upper end to the lower end of the fixed portion 73.

In the substrate support 11B, the gap between the first portion 60B1 and the inner surface of the electrostatic chuck 1111 and the one or more grooves of the support portion 75 extend between the inner surface of the electrostatic chuck 1111 and the respective side surfaces of the first portion 60B1 and the support portion 75. Therefore, in the substrate support 11B, the gap between the first portion 60B1 and the inner surface of the electrostatic chuck 1111 and the one or more grooves of the support portion 75 define the gas flow path F within the first through hole H1. Similarly, in the substrate support 11B, the one or more grooves G4 extend between the side surface of the fixed portion 73 and the inner surface of the large-diameter portion 51B, and define the gas flow path F within the second through hole H2.

In the substrate support 11B, the small-diameter portion 51A supports the fixed portion 73 from below, and the fixed portion 73 is fixed to the fixing portion 51 by the small-diameter portion 51A and the electrostatic chuck 1111 holding the fixed portion 73. This prevents the second member 70B from falling out of the sleeve 50B even if thermal contraction of the second member 70B occurs. Therefore, a change in the position of the first member 60B supported by the second member 70B within the first through hole H1 is suppressed. Hence, in the substrate support 11B, electrical discharge between the substrate W and the electrostatic chuck 1111 is suppressed.

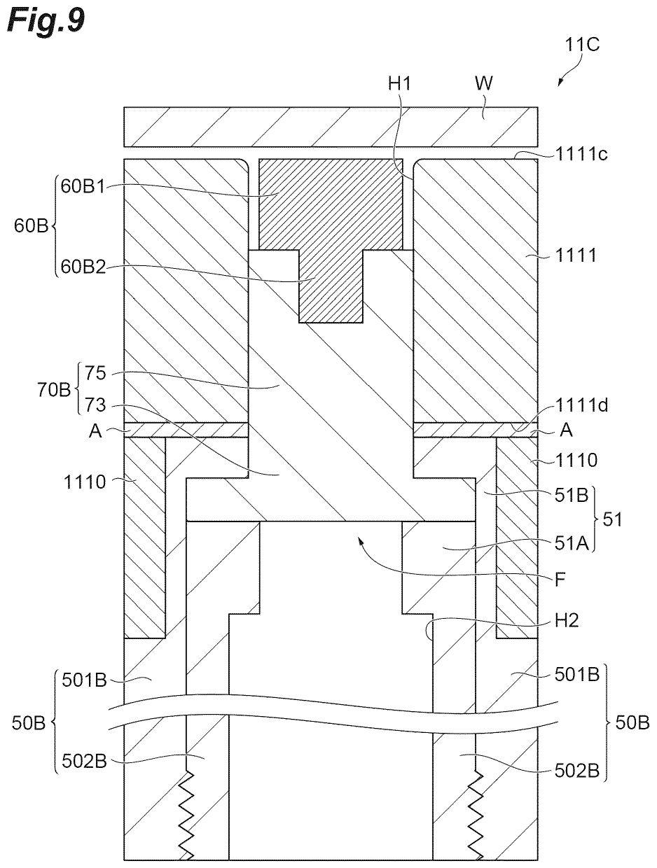

Next, a substrate support 11C according to yet another example embodiment will be described with reference to FIG. 9. FIG. 9 is a partially enlarged cross-sectional view illustrating the substrate support according to yet another example embodiment. In the following, the differences between the substrate support 11C illustrated in FIG. 9 and the substrate support 11B described above will be mainly described.

In the substrate support 11C, as illustrated in FIG. 9, the support portion 75 is within the first through hole H1 and within the second through hole H2. More specifically, in the substrate support 11C, the support portion 75 extends from the first through hole H1 to the second through hole H2.

In the substrate support 11C, the fixed portion 73 is held between the small-diameter portion 51A and the first sleeve 501B (or upper end portion thereof). This fixes the fixed portion 73 to the fixing portion 51.

In the substrate support 11C as well, even if thermal contraction of the second member 70B occurs, the second member 70B is prevented from falling out of the sleeve 50B. Therefore, in the substrate support 11C, electrical discharge between the substrate W and the electrostatic chuck 1111 is suppressed.

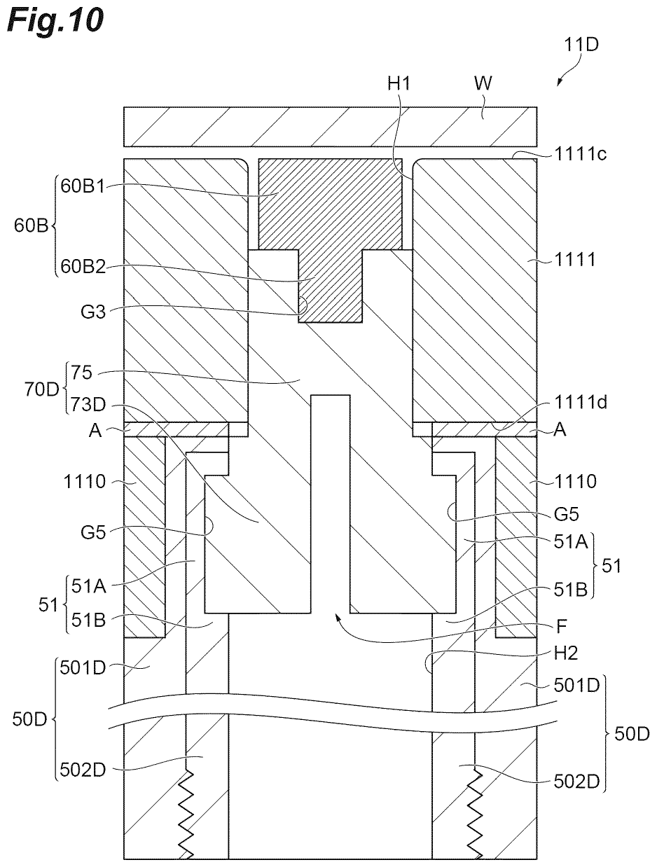

Next, a substrate support 11D according to yet another example embodiment will be described with reference to FIG. 10. FIG. 10 is a partially enlarged cross-sectional view illustrating the substrate support according to yet another example embodiment. In the following, the differences between the substrate support 11D illustrated in FIG. 10 and the substrate support 11B described above will be mainly described.

The substrate support 11D includes a sleeve 50D and a second member 70D in place of the sleeve 50B and the second member 70B. As illustrated in FIG. 10, the sleeve 50D includes a first sleeve 501D and a second sleeve 502D, similarly to the sleeve 50B. In the substrate support 11D, the second sleeve 502D includes the small-diameter portion 51A and the large-diameter portion 51B.

The inner surface of the second sleeve 502D defines a groove G5. Specifically, the groove G5 is formed above the small-diameter portion 51A and inside the large-diameter portion 51B.

The second member 70D includes a fixed portion 73D in addition to the support portion 75. The fixed portion 73D is continuous with the support portion 75 and extends downward from the support portion 75. The fixed portion 73D is configured to expand and contract in the radial direction with respect to the central axes of both the sleeve 50D and the second member 70D. The fixed portion 73D may be divided into a plurality of portions by two split grooves that intersect or are orthogonal to each other so as to expand and contract in the radial direction. The plurality of portions of the fixed portion 73D are guided to the groove G5 in a contracted state and elastically expand within the groove G5. Thus, the fixed portion 73D is and fixed above the small-diameter portion 51A and inside the large-diameter portion 51B. The bonding material A need not be disposed between the fixed portion 73D and the electrostatic chuck 1111.

Furthermore, in the substrate support 11D, similarly to the substrate support 11B, the gap between the first portion 60B1 and the inner surface of the electrostatic chuck 1111 and the groove of the support portion 75 extend between the inner surface of the electrostatic chuck 1111 and the respective side surfaces of the first portion 60B1 and the support portion 75. Therefore, in the substrate support 11D, the gap between the first portion 60B1 and the inner surface of the electrostatic chuck 1111 and the groove of the support portion 75 define the gas flow path F within the first through hole H1. Further, in the substrate support 11D, the two split grooves of the fixed portion 73D define the gas flow path F within the second through hole H2.

In the substrate support 11D as well, even if thermal contraction of the second member 70D occurs, the second member 70D is prevented from falling out of the sleeve 50D. Therefore, in the substrate support 11D as well, electrical discharge between the substrate W and the electrostatic chuck 1111 is suppressed.

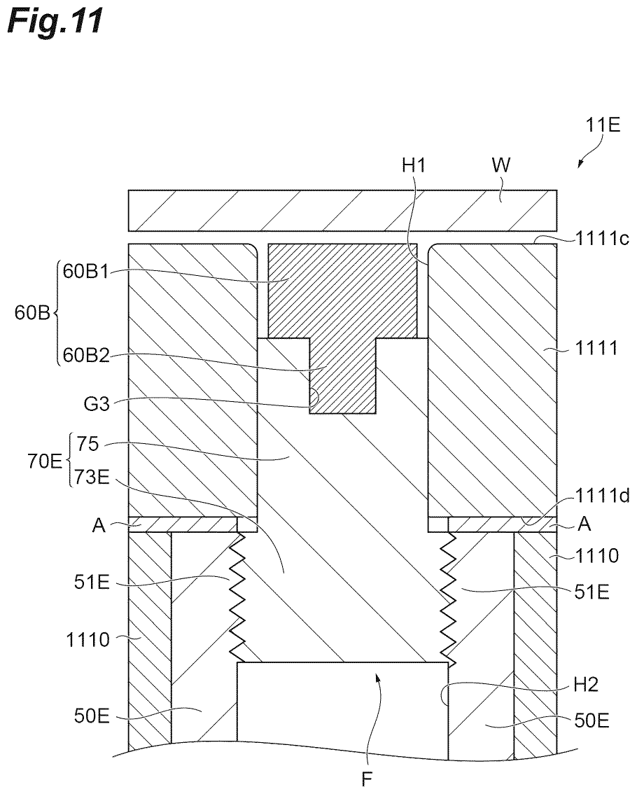

Next, a substrate support 11E according to yet another example embodiment will be described with reference to FIG. 11. FIG. 11 is a cross-sectional view illustrating the substrate support according to yet another example embodiment. In the following, the differences between the substrate support 11E illustrated in FIG. 11 and the substrate support 11B described above will be mainly described.

The substrate support 11E includes a sleeve 50E and a second member 70E in place of the sleeve 50B and the second member 70B. As illustrated in FIG. 11, in the substrate support 11E, the sleeve 50E is composed of a single member and has a single-layer structure. The sleeve 50E may be fixed to the base 1110 by a bonding layer (not illustrated). The sleeve 50E may also be detachably attached to the base 1110 without a bonding layer.

The sleeve 50E includes a fixing portion 51E. In the substrate support 11E, the fixing portion 51E defines the inner surface of a part of the sleeve 50E including the upper end of the sleeve 50E. Further, in the substrate support 11E, the fixing portion 51E includes an internal thread. More specifically, the inner surface of the sleeve 50E defined by the fixing portion 51E is provided with an internal thread.

The second member 70E includes a fixed portion 73E in addition to the support portion 75. The fixed portion 73E is continuous with the support portion 75. The fixed portion 73E includes an external thread that is threadedly engaged with the internal thread of the fixing portion 51E. More specifically, the outer surface of the fixed portion 73E is provided with the external thread. The second member 70E is fixed to the sleeve 50E by the external thread of the fixed portion 73E being threadedly engaged with the internal thread of the fixing portion 51E. The bonding material A need not be disposed between the fixed portion 73E and the electrostatic chuck 1111.

When the fixing portion 51E includes an internal thread, the width of the fixing portion 51E in the lateral direction is defined by the minimum distance between the inner surfaces of the sleeve 50E defined by the fixing portion 51E in the direction orthogonal to the central axes of both the sleeve 50E and the second member 70E. That is, when the fixing portion 51E includes an internal thread, the width of the fixing portion 51E in the lateral direction is defined by the minor diameter of the internal thread (the minimum diameter of the internal thread).

When the fixed portion 73E includes an external thread, the width of the fixed portion 73E in the lateral direction is defined by the maximum diameter of the external thread. That is, when the fixed portion 73E includes an external thread, the width of the fixed portion 73E in the lateral direction is defined by the nominal diameter of the external thread.

In the substrate support 11E, the gap between the first portion 60B1 and the inner surface of the electrostatic chuck 1111 and the groove of the support portion 75 extend between the inner surface of the electrostatic chuck 1111 and the respective side surfaces of the first portion 60B1 and the support portion 75. Therefore, in the substrate support 11E, the gap between the first portion 60B1 and the inner surface of the electrostatic chuck 1111 and the groove of the support portion 75 define the gas flow path F within the first through hole H1. Further, in the substrate support 11E, the gap between the external thread of the fixed portion 73E and the internal thread of the fixing portion 51E defines the gas flow path F within the second through hole H2.

In the substrate support 11E as well, even if thermal contraction of the second member 70E occurs, the second member 70E is prevented from falling out of the sleeve 50E. Therefore, in the substrate support 11E as well, electrical discharge between the substrate W and the electrostatic chuck 1111 is suppressed.

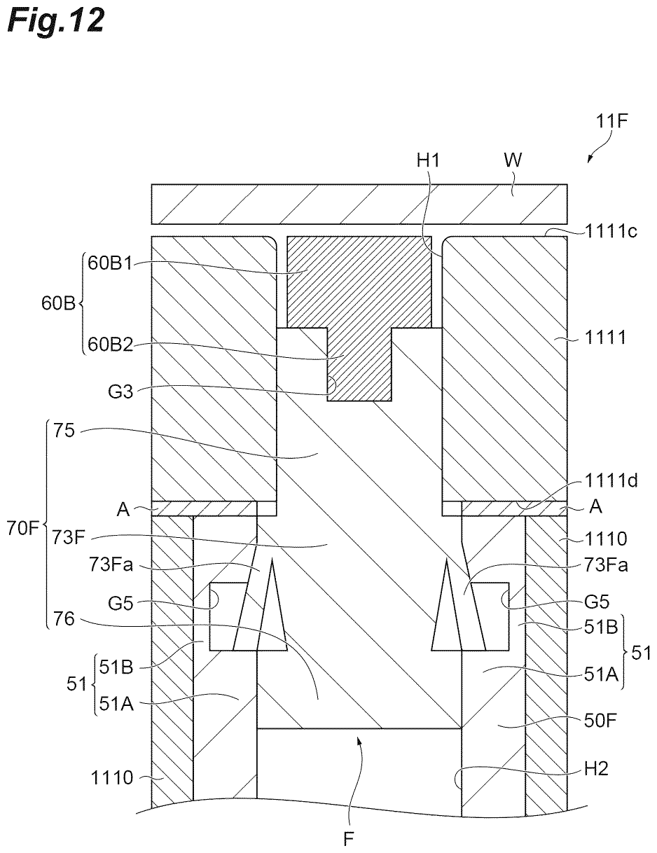

Next, a substrate support 11F according to yet another example embodiment will be described with reference to FIG. 12. FIG. 12 is a cross-sectional view illustrating the substrate support according to yet another example embodiment. In the following, the differences between the substrate support 11F illustrated in FIG. 12 and the substrate support 11B described above will be mainly described.

The substrate support 11F includes a sleeve 50F and a second member 70F in place of the sleeve 50B and the second member 70B.

As illustrated in FIG. 12, in the substrate support 11F, the sleeve 50F is a single member and has a single-layer structure. Therefore, in the substrate support 11F, the sleeve 50F includes the small-diameter portion 51A and the large-diameter portion 51B. The inner surface of the sleeve 50F defines a groove G5. The groove G5 is disposed above the small-diameter portion 51A and inside the large-diameter portion 51B.

The second member 70F includes a fixed portion 73F and a lower portion 76 in addition to the support portion 75. In the substrate support 11F, the fixed portion 73F is continuous with the support portion 75 and extends downward from the support portion 75. The fixed portion 73F is configured to expand and contract in the radial direction with respect to the central axes of both the sleeve 50F and the second member 70F. More specifically, the fixed portion 73F includes a plurality of claws 73Fa protruding outward from the side surface thereof to the outside of the second member 70F. The plurality of claws 73Fa are arranged along the circumferential direction on the side surface of the fixed portion 73F. The number of the plurality of claws 73Fa is, for example, “4”.

The plurality of claws 73Fa are configured to expand and contract in the radial direction with respect to the central axis. For example, each of the plurality of claws 73Fa may be fixed at upper end thereof and free at lower end thereof. In the substrate support 11F, the plurality of claws 73Fa are guided to the groove G5 while being pushed toward the center side of the fixed portion 73F, and elastically expand within the groove G5 by a restoring force. The plurality of claws 73Fa are pressed against the large-diameter portion 51B by their restoring force. Thus, the fixed portion 73F is fixed by the fixing portion 51. The bonding material A need not be disposed between the fixed portion 73F and the electrostatic chuck 1111.

The lower portion 76 is continuous with the fixed portion 73F and extends downward from the fixed portion 73F. The width of the lower portion 76 in the lateral direction is equal to or less than the width of the small-diameter portion 51A in the lateral direction. Therefore, in the substrate support 11F, the lower portion 76 is held from the lateral direction by the small-diameter portion 51A.

Furthermore, in the substrate support 11F, the side surface of the lower portion 76 defines one or more grooves (not illustrated). The one or more grooves extend from the upper end to the lower end of the side surface of the lower portion 76. For example, the side surface of the lower portion 76 may define a plurality of grooves as the one or more grooves. The plurality of grooves may be arranged along the circumferential direction. The number of the plurality of grooves is, for example, “3”.

The groove defined by the lower portion 76 forms a gap between the side surface of the lower portion 76 and the inner surface of the sleeve 50F defining the second through hole H2. This gap is formed from the upper end to the lower end of the side surface of the lower portion 76.

In the substrate support 11F, the gap between the first portion 60B1 and the inner surface of the electrostatic chuck 1111 and the groove of the support portion 75 extend between the inner surface of the electrostatic chuck 1111 and the respective side surfaces of the first portion 60B1 and the support portion 75. Therefore, in the substrate support 11F, the gap between the first portion 60B1 and the inner surface of the electrostatic chuck 1111 and the groove of the support portion 75 define the gas flow path F within the first through hole H1. Further, in the substrate support 11F, the spaces between the plurality of claws 73Fa and the gap between the groove of the lower portion 76 and the inner surface of the sleeve 50F define the gas flow path F within the second through hole H2.

In the substrate support 11F as well, even if thermal contraction of the second member 70F occurs, the second member 70F is prevented from falling out of the sleeve 50F. Therefore, in the substrate support 11F as well, electrical discharge between the substrate W and the electrostatic chuck 1111 is suppressed.

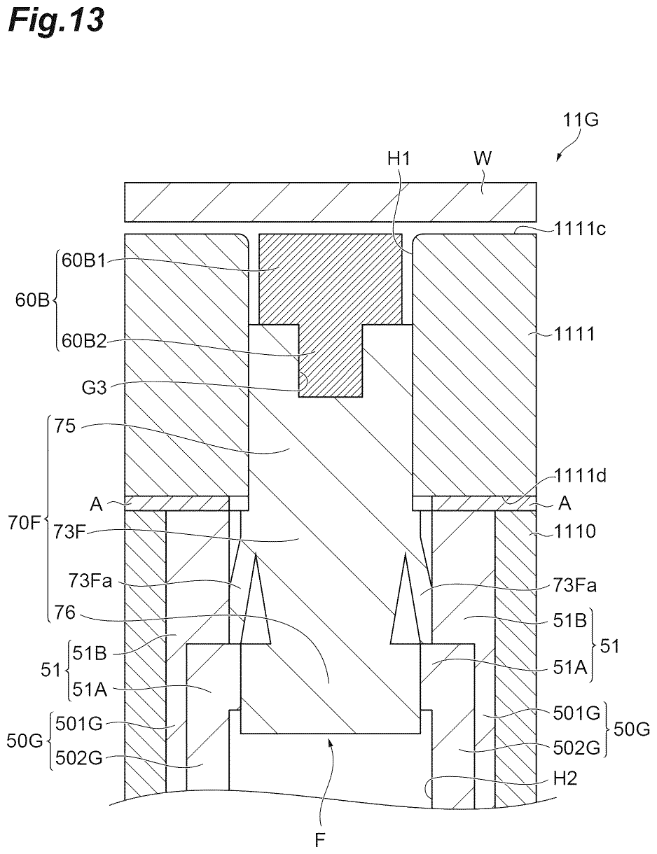

Next, a substrate support 11G according to yet another example embodiment will be described with reference to FIG. 13. FIG. 13 is a cross-sectional view illustrating the substrate support according to yet another example embodiment. In the following, the differences between the substrate support 11G illustrated in FIG. 13 and the substrate support 11F described above will be mainly described.

The substrate support 11G includes a sleeve 50G in place of the sleeve 50F. Unlike the sleeve 50F, the sleeve 50G has a two-layer structure. That is, the sleeve 50G includes a first sleeve 501G and a second sleeve 502G. In the substrate support 11G, the first sleeve 501G is fixed to the base 1110. The first sleeve 501G may be fixed to the base 1110 by a bonding layer (not illustrated). Alternatively, the first sleeve 501G may be detachably attached to the base 1110 without a bonding layer. The first sleeve 501G has a tubular shape.

The second sleeve 502G is disposed within the inner hole of the first sleeve 501G and is fixed to the first sleeve 501G. In the substrate support 11G, the first sleeve 501G and the second sleeve 502G may be threadedly engaged with each other at their lower end portions. The first sleeve 501G and the second sleeve 502G may be bonded to each other at their lower end portions by a bonding material such as an adhesive.

In the substrate support 11G, the second sleeve 502G configures to the small-diameter portion 51A, and the first sleeve 501G configures to the large-diameter portion 51B.

In the substrate support 11G, the fixed portion 73F is fixed to the fixing portion 51 by the small-diameter portion 51A supporting the fixed portion 73F from below and the fixed portion 73F being pressed against the large-diameter portion 51B by the restoring force of the plurality of claws 73Fa. Furthermore, in the substrate support 11G as well, the lower portion 76 is also fixed to the fixing portion 51 by the lower portion 76 being held from the lateral direction by the small-diameter portion 51A. In the substrate support 11G as well, similarly to the substrate support 11F, the bonding material A need not be disposed between the fixed portion 73F and the electrostatic chuck 1111.

In the substrate support 11G, the gap between the first portion 60B1 and the inner surface of the electrostatic chuck 1111 and the groove of the support portion 75 extend between the inner surface of the electrostatic chuck 1111 and the respective side surfaces of the first portion 60B1 and the support portion 75. Therefore, in the substrate support 11G, the gap between the first portion 60B1 and the inner surface of the electrostatic chuck 1111 and the groove of the support portion 75 define the gas flow path F within the first through hole H1. Further, in the substrate support 11F, the spaces between the plurality of claws 73Fa and the groove of the lower portion 76 extend between the second member 70F and the inner surface of the second sleeve 502G, and define the gas flow path F within the second through hole H2.

In the substrate support 11G as well, even if thermal contraction of the second member 70G occurs, the second member 70G is prevented from falling out of the sleeve 50G. Therefore, in the substrate support 11G as well, electrical discharge between the substrate W and the electrostatic chuck 1111 is suppressed.

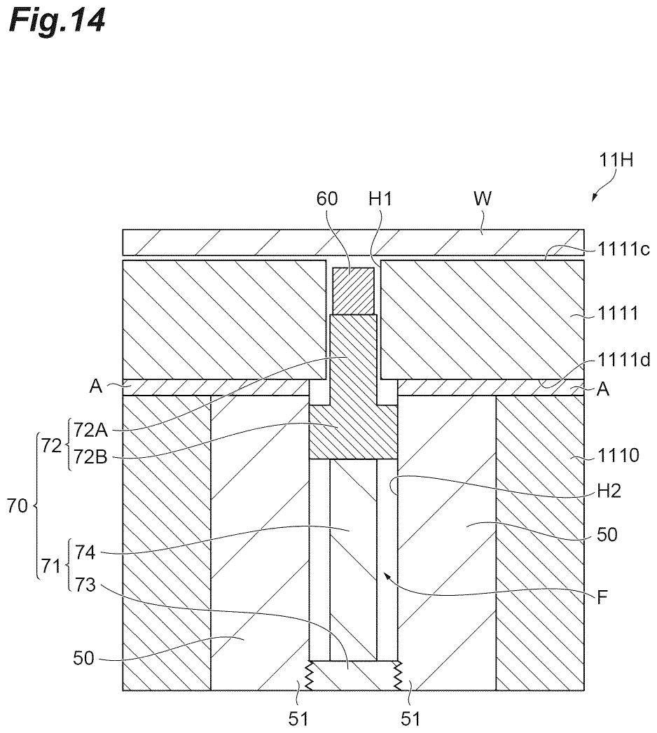

Next, a substrate support 11H according to yet another example embodiment will be described with reference to FIG. 14. FIG. 14 is a cross-sectional view illustrating the substrate support according to yet another example embodiment. The differences between the substrate support 11H illustrated in FIG. 14 and the substrate support 11 described above will be mainly described.

In the substrate support 11, the fixed portion 73 and the body 74 are continuous with each other, but in the substrate support 11H, the fixed portion 73 and the body 74 are not continuous with each other. That is, in the substrate support 11H, the fixed portion 73 and the body 74 are configured as separate members from each other. The body 74 may be held between the fixed portion 73 and the second rod 72. When the body 74 is held between the fixed portion 73 and the second rod 72, the body 74 may support the second rod 72 disposed thereon within the second through hole H2, and the fixed portion 73 may support the body 74 disposed thereon. The body 74 and the fixed portion 73 may be joined to each other. When the body 74 and the fixed portion 73 are joined to each other, the body 74 may be press-fitted into the fixed portion 73.

When the fixed portion 73 and the body 74 are configured as separate members from each other, the fixed portion 73 and the body 74 may include different materials from each other. In the substrate support 11H, the fixed portion 73 may include a resin. The resin forming the fixed portion 73 may be, for example, polytetrafluoroethylene. The body 74 may include ceramic. The ceramic forming the body 74 may be, for example, alumina.

Although various example embodiments have been described above, various additions, omissions, substitutions, and changes may be made without being limited to the example embodiments described above. It is also possible to combine elements in different embodiments to form other embodiments.

Here, various example embodiments included in the present disclosure are described in [E1] to [E19] below.

### [E1]

A substrate support comprising:
a base;
an electrostatic chuck on the base, the electrostatic chuck having a first surface including a substrate supporting surface and a second surface on the opposite side from the first surface, and defining a first through hole penetrating from the first surface to the second surface;
a tubular sleeve fixed within the base, the sleeve defining, as an inner hole thereof, a second through hole that is aligned with the first through hole and communicates with the first through hole;
a first member within the first through hole; and
a columnar second member that supports the first member and is at least within the second through hole,
wherein
the first member and the second member define a gas flow path within the first through hole and within the second through hole,
the sleeve includes a fixing portion that partially defines an inner surface of the sleeve,
the second member includes a fixed portion that is fixed by the fixing portion, and
a width of the fixing portion in a lateral direction orthogonal to central axes of both the sleeve and the second member is smaller than a width of the fixed portion in the lateral direction.

### [E2]

The substrate support according to E1, wherein
the fixing portion includes an internal thread, and
the fixed portion includes an external thread threadedly engaged with the internal thread.

[E3]

The substrate support according to E2, wherein
the second member includes:
   a first rod having a columnar shape and including the fixed portion; and
   a second rod having a columnar shape and extending between the first rod and the first member.

### [E4]

The substrate support according to E3, wherein
the first rod includes ceramic, and
the second rod includes polytetrafluoroethylene.

### [E5]

The substrate support according to E2, wherein
the first through hole is a counterbore, and
the first member abuts against a surface defining the counterbore.

### [E6]

The substrate support according to E5, The substrate support according to claim 5, wherein
the second member includes ceramic.

### [E7]

The substrate support according to E1, wherein
the fixing portion includes:
   a small-diameter portion having a diameter smaller than the width of the fixed portion; and
   a large-diameter portion having a diameter that is larger than the width of the fixed portion and is above the small-diameter portion, and
the fixed portion is above the small-diameter portion and inside the large-diameter portion.

### [E8]

The substrate support according to E7, wherein
the fixed portion is held between the small-diameter portion and the electrostatic chuck.

### [E9]

The substrate support according to E7, wherein
the fixed portion is configured to expand and contract in a radial direction with respect to the central axes.

### [E10]

The substrate support according to E9, wherein
the large-diameter portion is a groove of the sleeve.

### [E11]

The substrate support according to E7, wherein
the sleeve includes:
   a first sleeve having a tubular shape; and
   a second sleeve having a tubular shape, disposed within an inner hole of the first sleeve, and fixed to the first sleeve,
the second sleeve configures the small-diameter portion, and
the first sleeve configures the large-diameter portion.

### [E12]

The substrate support according to any one of E7 to E11, wherein
the second member includes polytetrafluoroethylene.

### [E13]

A substrate support comprising:
a base;
an electrostatic chuck on the base, the electrostatic chuck having a first surface including a substrate supporting surface and a second surface on the opposite side from the first surface, and defining a first through hole penetrating from the first surface to the second surface;
a tubular sleeve fixed within the base, the sleeve defining, as an inner hole thereof, a second through hole that is aligned with the first through hole and communicates with the first through hole;
a first member within the first through hole; and
a columnar second member that supports the first member and is at least within the second through hole,
wherein
the first member and the second member define a gas flow path within the first through hole and within the second through hole,
the sleeve includes a fixing portion that partially defines an inner surface of the sleeve,
the second member includes a fixed portion that is fixed by the fixing portion,
the fixing portion includes an internal thread, and
the fixed portion includes an external thread threadedly engaged with the internal thread.

### [E14]

The substrate support according to E13, wherein
the second member includes:
   a first rod having a columnar shape and including the fixed portion; and
   a second rod having a columnar shape and extending between the first rod and the first member.

### [E15]

The substrate support according to E14, wherein
the first rod includes ceramic, and
the second rod includes polytetrafluoroethylene.

### [E16]

The substrate support according to E13, wherein
the first through hole is a counterbore, and
the first member abuts against a surface defining the counterbore.

### [E17]

The substrate support according to E16, wherein
the second member includes ceramic.

### [E18]

The substrate support according to any one of E1 to E17, wherein
the first member includes silicon carbide or ceramic.

### [E19]

A plasma processing apparatus comprising:
a plasma processing chamber defining a processing space therein; and
a substrate support according to claim 1, the substrate support being within the plasma processing chamber.

From the above description, it will be understood that various embodiments of the present disclosure have been described herein for purposes of illustration, and that various modifications may be made without departing from the scope and spirit of the present disclosure. Accordingly, the various embodiments disclosed herein are not intended to be limiting, and the true scope and spirit are indicated by the appended claims.

What is claimed is:

1. A substrate support comprising:
a base;
an electrostatic chuck on the base, the electrostatic chuck having a first surface including a substrate supporting surface and a second surface on the opposite side from the first surface, and defining a first through hole penetrating from the first surface to the second surface;
a tubular sleeve fixed within the base, the sleeve defining, as an inner hole thereof, a second through hole that is aligned with the first through hole and communicates with the first through hole;
a first member within the first through hole; and
a columnar second member that supports the first member and is at least within the second through hole,
wherein
the first member and the second member define a gas flow path within the first through hole and within the second through hole,
the sleeve includes a fixing portion that partially defines an inner surface of the sleeve,
the second member includes a fixed portion that is fixed by the fixing portion, and
a width of the fixing portion in a lateral direction orthogonal to central axes of both the sleeve and the second member is smaller than a width of the fixed portion in the lateral direction.

2. The substrate support according to claim 1, wherein
the fixing portion includes an internal thread, and
the fixed portion includes an external thread threadedly engaged with the internal thread.

3. The substrate support according to claim 2, wherein
the second member includes:
a first rod having a columnar shape and including the fixed portion; and
a second rod having a columnar shape and extending between the first rod and the first member.

4. The substrate support according to claim 3, wherein
the first rod includes ceramic, and
the second rod includes polytetrafluoroethylene.

5. The substrate support according to claim 2, wherein
the first through hole is a counterbore, and
the first member abuts against a surface defining the counterbore.

6. The substrate support according to claim 5, wherein
the second member includes ceramic.

7. The substrate support according to claim 1, wherein
the fixing portion includes:
a small-diameter portion having a diameter smaller than the width of the fixed portion; and
a large-diameter portion having a diameter that is larger than the width of the fixed portion and is above the small-diameter portion, and
the fixed portion is above the small-diameter portion and inside the large-diameter portion.

8. The substrate support according to claim 7, wherein
the fixed portion is held between the small-diameter portion and the electrostatic chuck.

9. The substrate support according to claim 7, wherein
the fixed portion is configured to expand and contract in a radial direction with respect to the central axes.

10. The substrate support according to claim 9, wherein
the large-diameter portion is a groove of the sleeve.

11. The substrate support according to claim 7, wherein
the sleeve includes:
a first sleeve having a tubular shape; and
a second sleeve having a tubular shape, disposed within an inner hole of the first sleeve, and fixed to the first sleeve,
the second sleeve configures the small-diameter portion, and
the first sleeve configures the large-diameter portion.

12. The substrate support according to claim 7, wherein
the second member includes polytetrafluoroethylene.

13. A substrate support comprising:
a base;
an electrostatic chuck on the base, the electrostatic chuck having a first surface including a substrate supporting surface and a second surface on the opposite side from the first surface, and defining a first through hole penetrating from the first surface to the second surface;
a tubular sleeve fixed within the base, the sleeve defining, as an inner hole thereof, a second through hole that is aligned with the first through hole and communicates with the first through hole;
a first member within the first through hole; and
a columnar second member that supports the first member and is at least within the second through hole,
wherein
the first member and the second member define a gas flow path within the first through hole and within the second through hole,
the sleeve includes a fixing portion that partially defines an inner surface of the sleeve,
the second member includes a fixed portion that is fixed by the fixing portion,
the fixing portion includes an internal thread, and
the fixed portion includes an external thread threadedly engaged with the internal thread.

14. The substrate support according to claim 13, wherein
the second member includes:
a first rod having a columnar shape and including the fixed portion; and
a second rod having a columnar shape and extending between the first rod and the first member.

15. The substrate support according to claim 14, wherein
the first rod includes ceramic, and
the second rod includes polytetrafluoroethylene.

16. The substrate support according to claim 13, wherein
the first through hole is a counterbore, and
the first member abuts against a surface defining the counterbore.

17. The substrate support according to claim 16, wherein
the second member includes ceramic.

18. The substrate support according to claim 1, wherein
the first member includes silicon carbide or ceramic.

19. A plasma processing apparatus comprising:
a plasma processing chamber defining a processing space therein; and
a substrate support according to claim 1, the substrate support being within the plasma processing chamber.
